(19) United States
(12) Patent Application Publication
(10) Pub. No.: US 2004/0038537 A1
(43) Pub. Date: Feb. 26, 2004

(54) Method of preventing or suppressing sidewall buckling of mask structures used to etch feature sizes smaller than 50nm

(76) Inventors: Wei Liu, San Jose, CA (US); Christopher Dennis Bencher, San Jose, CA (US); David S. L. Mui, Fremont, CA (US)

Correspondence Address: PATENT COUNSEL, APPLIED MATERIALS, INC., Legal Affairs Department, P.O.BOX 450A, Santa Clara, CA, 95052, US

(21) Appl. No.: 10/225,028

(22) Filed: Aug. 20, 2002

(51) Int. Cl. H01L 21/311

(52) U.S. Cl. 438/694

(57) ABSTRACT

We have discovered a method of preventing or suppressing the buckling of amorphous hard mask structures used to etch feature sizes smaller than about 50 nm. We have determined that buckling of the hard mask can be prevented by controlling the aspect ratio of mask features to be within a certain range when the features are sub 40-50 nm in size. In the case of amorphous hard mask structures, generally the aspect ratio of a feature should be controlled to be less than about 3 when the feature size is sub 40-50 nm in size; and, depending on the substrate to which the hard mask is adhered, the aspect ratio may need to be as low as about 1.0 or lower to ensure that there is no buckling of the hard mask sidewalls.

This application is related to application Ser. No. 09/590,322 filed Jun. 8, 2000 and entitled: “Method of Depositing Amorphous Carbon Layer”; and, to application Ser. No. 09/905,172 filed Jul. 13, 2001 and entitled: “Etch Pattern Definition Using A CVD Organic Layer As An Anti-Reflection Coating And Hardmask.”

### BACKGROUND OF THE INVENTION

1. Field of the Invention

The present invention pertains to a method of suppressing the tendency for sidewall buckling in masking structures used to etch semiconductor features. The invention is particularly useful when the composition of the masking structure is amorphous in nature.

2. Brief Description of the Background Art

Integrated circuit manufacturing processes often involve the creation of etch patterns in various materials by selective etching. Usually the etched patterns are produced by providing a mask on the surface to be etched and then etching through apertures in the mask. The resulting etched structure may be further processed to produce a particular device structure. For example, trenches etched in a polysilicon substrate may be filled with an electrically insulating material to facilitate inter-device isolation. Capacitive storage may be produced by lining a trench in a single crystal silicon substrate with layers of conductive material. Vertical electrical interconnects between multiple conductive layers may be provided by etching a contact via through a dielectric layer which separates multiple conductive layers and then filling the contact via with a conductive material.

Photoresists are typically employed to provide a patterning mask over a substrate to be etched. The required thickness of a patterned photoresist layer depends on the thickness of the underlying substrate which is to be etched and the etch selectivity of the underlying substrate material relative to the photoresist material. The feature size in the patterned photoresist layer has grown smaller and smaller as the need for smaller device features has progressed. As the pattern dimensions are reduced, the thickness of the radiation sensitive resist must correspondingly be reduced in order to control pattern resolution. However, the thinner resist layer may then be etched away before the pattern is etched (transferred) all the way through the underlying substrate. This problem has led to the development of a dual masking system, where a patterned photoresist layer is used as a mask to transfer the pattern through a thin layer of a more etch-resistant material (a hard mask) which is then used to transfer the pattern through a substrate underlying the hard mask.

While the photoresist material typically includes an organic polymer base, the hard mask material is typically an inorganic material such a silicon dioxide, silicon nitride, or silicon oxynitride. While these materials function well in terms of selectivity relative to underlying substrate materials, residual hard masking material is frequently difficult to remove from the underlying substrate surface. To alleviate this problem the present inventors worked as part of a team developing a CVD-deposited amorphous carbon hard mask, the residue of which could be easily removed by exposure to an oxygen-based plasma. A method of depositing the amorphous carbon layer on a substrate surface is described in application Ser. No. 09/590,322 filed Jun. 8, 2000 and entitled: “Method of Depositing Amorphous Carbon Layer”, assigned to the assignee of the present invention. The subject matter of the '322 application is hereby incorporated by reference in its entirety.

In particular, the '322 application provides a method for forming an amorphous carbon layer for use in integrated circuit fabrication. The amorphous carbon layer is formed by thermally decomposing a gas mixture comprising a hydrocarbon compound and an inert gas. The gas mixture, which may optionally include an additive gas, is introduced into a process chamber where plasma enhanced thermal decomposition of the hydrocarbon compound in close proximity to a substrate surface, results in deposition of an amorphous carbon layer on the substrate surface. The method is described in more detail below for an amorphous carbon layer deposited on a substrate in a processing chamber of the kind available in a CENTURA® system, PRECISION 5000® system, or a PRODUCER™ system equipped with a PRODUCER TWIN™ processing chamber or a CENTURA DXZ™ processing chamber, all available from Applied Materials, Inc., Santa Clara, Calif.

The method for forming an amorphous carbon layer on a substrate surface includes: providing a gas mixture to a deposition chamber in which the substrate surface is positioned, wherein the gas mixture comprises one or more hydrocarbon compounds and an inert gas; and heating the gas mixture to thermally decompose the one or more hydrocarbon compounds in the gas mixture to form an amorphous carbon layer on the substrate. Typically, the one or more hydrocarbon compounds in the gas mixture have the general formula CₓH_{y}, wherein x has a range of 2 to 4 and y has a range of 2 to 10. Some of the hydrocarbon compounds which work well include propylene (C₃H₆), propyne (C₃H₄), propane (C₃H₈), butane (C₄H₁₀), butylene (C₄H₈), butadiene (C₄H₆), or acetylene (C₂H₂) and combinations thereof. Propylene works particularly well.

The inert gas used in combination with the at least one hydrocarbon compound is typically selected from the group consisting of helium, argon and combinations thereof. In addition to the inert gas, an additive gas may be included in the decomposing gas mixture, where the additive gas is typically selected from the group consisting of ammonia, nitrogen, hydrogen, and combinations thereof.

The substrate is heated to a temperature between about 100° C. and about 600° C.; the deposition chamber is maintained at a pressure between about 1 Torr to about 20 Torr; and the gas mixture is provided to the deposition chamber at a flow rate in a range of about 50 sccm to about 500 sccm. The gas mixture is often heated by application of an electric field which is typically produced using radio frequency (RF) power. The RF power applied is generally in a range of about 3 W/in² to about 20 W/in².

An as-deposited amorphous carbon layer has an adjustable carbon: hydrogen ratio that ranges from about 10% hydrogen to about 60% hydrogen. The amorphous carbon layer also has a light absorption coefficient, k, that can be varied between about 0.1 to about 1.0 at wavelengths below about 250 nm, making it suitable for use as an anti-reflective coating (ARC) at DUV wavelengths.

In addition to the advantage of easy removal from the substrate surface, an amorphous carbon hard mask can be deposited by CVD at temperatures ranging from about 100° C. to about 600° C. Since etching processes are carried out throughout processing of a semiconductor device (from beginning through “back-end” processing) it is important that a low thermal budget hard mask be available for instances when a low substrate temperature is necessary to protect device elements present in a substrate. In such a circumstance, the CVD deposition temperature is more typically in the range of about 350° C. to about 500° C. Crystalline hard masking materials typically require formation/application temperatures in excess of 500° C. Many of the crystalline-comprising materials suitable for use as a hard mask are metals, and metals cannot be used in many instances where contamination by a conductive material may be problematic, such as during the etch of a polysilicon gate layer. In addition, crystalline masking materials have grain boundaries which, upon etching may produce roughness along pattern etches which reduces mask resolution.

Applicants have developed processes for etching underlying substrates such as polysilicon through an amorphous carbon hard mask. Typically the photoresist used to transfer a pattern to a hard mask is a 193 nm or 248 nm DUV photoresist which is subsequently trimmed to enable etching of feature sizes on the order of about 50 nm or smaller. The amorphous carbon hard masking material acts as an antireflective coating (ARC) beneath a photoresist layer while the photoresist layer is pattern imaged by radiation. Subsequently, after transfer of a pattern from the photoresist through an underlying amorphous carbon layer, the amorphous carbon layer is used as a hard mask to transfer the pattern to an underlying substrate. Often, a dielectric ARC such as silicon oxynitride is used between the photoresist layer and the amorphous carbon layer to provide phase shift cancellation during imaging of the photoresist material by DUV radiation. In addition, the dielectric ARC may be used to protect the amorphous carbon during photoresist stripping and during optional trimming of the etched amorphous carbon hard mask.

The process for etching underlying substrates through an amorphous carbon hard mask is described in detail in application Ser. No. 09/905,172 filed Jul. 13, 2001 and entitled: “Etch Pattern Definition Using A CVD Organic Layer As An Anti-Reflection Coating And Hardmask”. The '172 application is assigned to the assignee of the present invention and is hereby incorporated by reference it its entirety.

During development of etching processes employing an amorphous carbon hard mask, we discovered that when the hard mask feature size is about 50 nm or less, it is not uncommon to observe sidewall buckling of mask features.

For example, FIG. 1A shows a typical etch stack structure 100 prior to patterning of an amorphous carbon hard mask. From bottom to top, the underlying substrate 102 is single crystal silicon wafer which was typically about 750 μm to about 850 μm thick (depending on the wafer size); overlying the single crystal silicon substrate 102 is a layer of silicon oxide 104 which is typically about 10 Å to about 20 Å thick. Overlying the silicon oxide layer 104 is a layer of polysilicon 106 which is typically about 1,000 Å to about 2, 000 Å thick; overlying the polysilicon layer 106 is a layer of amorphous carbon 108 which is typically about 400 Å to about 800 Å thick. Overlying the amorphous carbon layer 108 is a layer of silicon oxynitride 110 which is about 150 Å to about 350 Å thick; and overlying the silicon oxynitride layer 110 is a patterned photoresist mask 112 which was imaged using a 248 nm DUV source of radiation and then developed to provide the pattern. The photoresist layer is commonly about 3,000 Å to about 5,000 Å thick. The thickness of the photoresist layer is typically based on the thickness of the underlaying layers which are to be patterned using the photoresist and the etch selectivity of the photoresist relative to those underlying layers. In FIG. 1A, the pattern is one of lines 114 and spaces 116. The line width “w” of the lines was about 38 nm, as trimmed from the originally developed photoresist lines. The space 116 width “s” between the lines 114 was larger than about 150 nm, with the size of the space depending on the device being fabricated.

FIG. 1B shows the etch stack structure 100 of FIG. 1A after transfer of the etch pattern through the amorphous carbon masking layer 108. The patterned photoresist layer 112 was consumed during transfer of the pattern through the underlying layer 110 of silicon oxynitride and the amorphous carbon masking layer 108. A portion of the patterned silicon oxynitride layer 110 remains atop patterned amorphous carbon masking layer 108. FIG. 1C shows a top view of FIG. 1B, and illustrates that the 38 nm wide lines 114 are straight lines.

FIG. 1D shows the etch stack structure 100 of FIG. 1B after transfer of the pattern through about 35% of the polycrystalline silicon layer 106. By this time in the process, the silicon oxynitride layer 110 has been completely removed. FIG. 1E shows a top view of FIG. 1D. The 38 nm wide lines 114 exhibit a constant critical dimension (line width), but are buckled, providing an unacceptable variation in the alignment of lines 114, and in some instances, a break in the lines 114 (not shown) may even appear.

It is readily apparent that the distortions in the lines 114 of the patterned masking layer 108 need to be prevented, or at least suppressed, when the line width is in the range of 38 nm, to provide an acceptable line profile.

### SUMMARY OF THE INVENTION

We have discovered a method of preventing or suppressing the buckling of amorphous hard mask structures used to etch feature sizes smaller than about 50 nm. When the hard mask buckles, underlying substrate which is etched using the hard mask is etched in the buckled pattern rather than the desired pattern. We have determined that buckling of the hard mask can be prevented or suppressed by controlling the aspect ratio of mask features which are sub 40-50 nm in size. In particular, the term “aspect ratio” refers to the ratio of the height dimension to the width dimension of the feature. For example, when the feature is a line, the aspect ratio is the ratio of the line sidewall height to the line width. To avoid sidewall buckling, the line width used in calculating what the aspect ratio of the hard mask should be controlled to is typically the minimal line width in a given mask feature (which is generally referred to as the critical dimension of “CD”).

In the case of amorphous hard mask structures, the aspect ratio of a feature should on average be controlled to be less than about 2 when the feature size is sub 40-50 nm in size. A more precise determination of what the aspect ratio may be controlled to can be estimated by taking into account the substrate to which the hard mask is adhered and by taking into account any capping layers which may be present on the surface of the hard mask which is not adhered to the substrate. For example, when the substrate to which the hard mask is adhered is a polycrystalline substrate, the aspect ratio may need to be as low as about 1.0 or lower to ensure that there is no buckling of the hardmask sidewall.

As mentioned above, the maximum aspect ratio which may be used without risk that hard mask sidewall buckling will occur depends in part on the composition of the substrate to which the hard mask structure is adhered. Based on our data, when the substrate is a single crystal substrate, such as single crystal silicon (by way of example and not by way of limitation), there is an opportunity to achieve better adhesion to the substrate surface. Controlling the hard mask aspect ratio to about 2.7 or less is expected to prevent buckling of the sidewalls of a hardmask adhered to a single crystal silicon substrate. It appears that when the substrate is polycrystalline, so that grain boundary layers are present, the adhesion of an amorphous hard mask material to the substrate surface is reduced, and the control of the aspect ratio needs to take into account the average grain size of the polycrystalline substrate as well as the critical dimension size of the hard mask. For example, for polycrystalline silicon, which has an average grain size of about 50 mm, when the hard mask has a feature size critical dimension in the range of sub 40 nm, controlling the aspect ratio to be about 1.6 or less prevents buckling of the hardmask feature. As the amorphous hard mask feature size becomes smaller relative to a given polycrystalline substrate grain size, so that grain boundaries have an increased affect on adhesion of the amorphous hard mask, it is advisable to control the aspect ratio of the hard mask sidewall height to line width to be about 1 or less. In general, the worse the adhesion to the substrate, the lower the aspect ratio needs to be for a given hard mask critical dimension (line width critical dimension, for example).

It is possible to use a higher aspect ratio amorphous hard mask feature than those described above when the hard mask is restrained at the bottom by good adhesion to a substrate and at the top by adhesion to a capping layer, such as silicon oxynitride, for example. However, in instances when it is not desirable to leave a capping layer in the device structure, or it is necessary to remove material beneath a capping layer, it may be necessary to use specific additional steps to remove the capping layer.

In instances where the underlying layer etched through an amorphous hard mask is an amorphous layer, that amorphous layer will behave in a manner similar to that described with respect to the amorphous hard mask. Thus, to avoid buckling of the sidewalls of a pattern etched underlying amorphous layer, it is important to maintain the aspect ratio of the etched sidewall height to the etched sidewall width within the ranges described above.

### BRIEF DESCRIPTION OF THE DRAWINGS

FIG. 1A shows a schematic cross-sectional view of an etch stack structure 100 of the kind useful in illustrating the invention. The bottom layer is a single crystal silicon substrate 102. A silicon oxide layer 104 overlies single crystal silicon substrate 102. A layer of polysilicon 106 overlies silicon oxide layer 104. An amorphous carbon layer 108 overlies polysilicon layer 106. A silicon oxynitride layer 110 overlies amorphous carbon layer 108, and a patterned photoresist layer 112 overlies silicon oxynitride layer 110.

FIG. 1B shows a schematic cross-sectional view of the etch stack structure 100 of FIG. 1A, subsequent to transferring the pattern from photoresist mask 112 through silicon oxynitride layer 110 and through amorphous carbon layer 108.

FIG. 1C shows a schematic top-view of the structure shown in FIG. 1B, illustrating the lines 114 and spaces 116 pattern on the upper surface of the structure 100.

FIG. 1D shows a schematic cross-sectional view of the etch stack structure 100 of FIG. 1B, subsequent to transferring the pattern approximately 35% of the way through polysilicon layer 106. Silicon oxynitride layer 110 residue has been completely removed during the continued etching.

FIG. 1E shows a schematic top-view of the structure shown in FIG. 1D, illustrating the lines 114 and spaces 116 pattern on the upper surface of the structure 100, and further illustrating the distortion in the profiles of lines 114 which is also evident in FIG. 1D.

FIG. 2A illustrates a CENTURA® Integrated Processing System 200 of the kind which was used during the experimentation leading to the present invention.

FIG. 2B shows a schematic of an individual CENTURA® DPS™ inductively coupled etch chamber 202 of the kind which was used during the majority of experimentation leading to the present invention.

FIG. 3A shows a schematic cross-sectional view of an etch stack for etching a polysilicon substrate using an amorphous carbon hard mask.

FIG. 3B shows a top view of etched 91 nm wide polysilicon lines etched from the etch stack shown in FIG. 3A.

FIG. 3C shows a top view of etched 75 nm wide polysilicon lines etched from the etch stack shown in FIG. 3A.

FIG. 3D shows a top view of etched 56 nm wide polysilicon lines etched from the etch stack shown in FIG. 3A.

FIG. 3E shows a top view of etched 50 nm wide polysilicon lines etched from the etch stack shown in FIG. 3A.

FIG. 3F shows a top view of etched 47 nm wide polysilicon lines etched from the etch stack shown in FIG. 3A.

FIG. 3G shows a top view of etched 38 nm wide polysilicon lines etched from the etch stack shown in FIG. 3A.

FIG. 3H shows a top view of etched 34 nm wide polysilicon lines etched from the etch stack shown in FIG. 3A.

FIG. 3I shows a top view of etched 25 mm wide polysilicon lines etched from the etch stack shown in FIG. 3A.

FIG. 4A shows a schematic cross-sectional view of an etch stack 400 for etching a layer of silicon nitride using a photoresist mask.

FIG. 4B shows a schematic cross-sectional view of the etched silicon nitride 406, and etched underlying layers, after etching of the etch stack shown in FIG. 4A.

FIG. 4C shows a schematic top view of an etched 31 nm wide silicon nitride line 412 from the structure 400 shown in FIG. 4B.

FIG. 5A shows a three dimensional structure 500 including a substrate 504 with an amorphous masking film 506 applied over a substrate 504.

FIG. 5B shows that due to the aspect ratio of the amorphous masking film 506 being less than 1, since h is considerable smaller than w, there is no buckling of the masking film 506 in the x-y plane.

FIG. 5C shows a three dimensional structure 501 including a substrate 505 with an amorphous masking film 507 applied over the substrate 505, where the aspect ratio of the amorphous masking film is in the range of about 3, for example.

FIG. 5D shows that due to the aspect ratio of amorphous masking film 507, there is buckling of the sidewall 520 patterned amorphous masking film 507 in the x-y plane.

FIG. 6A is a bar graph 600 showing the tendency of an amorphous carbon mask feature present on a polysilicon substrate surface to buckle, as a function of the aspect ratio of the mask feature. In particular, the critical dimension line width 602 for the mask feature is shown from left to right on the bar graph, while the thickness 604 of the hardmask (the height of a line feature) is shown on the left hand side of the bar graph.

FIG. 6B shows a schematic top view of an amorphous carbon mask line feature which has a height of 120 nm and a width (critical dimension, CD) of 47 nm.

FIG. 6C shows a schematic top view of an amorphous carbon mask line feature which has a height of 120 nm and a CD of 38 nm.

FIG. 6D shows a schematic top view of an amorphous carbon mask line feature which has a height of 40 nm and a CD of 25 nm.

FIG. 6E shows a schematic top view of an amorphous carbon mask line feature which has a height of 40 nm and a CD of 28 nm.

FIG. 6F shows a schematic top view of an amorphous carbon mask line feature which has a height of 20 nm and a CD of 22 nm.

FIG. 7A shows an amorphous mask film 704 overlying a polycrystalline substrate 702, with microscopic point stress 706 illustrated within the mask film 704.

FIG. 7B shows an amorphous mask film 714 overlying a polycrystalline substrate 712, adhered at points 713 to substrate 712 and not adhered at points 715.

FIG. 7C shows an amorphous mask film 724 overlying a polycrystalline substrate 722, adhered at points 723 to substrate 722 and not adhered at points 725. There is a beginning tendency of the mask film 724 to buckle, due to a combination of the aspect ratio of the mask film 724 and the fact that the line width “w” of mask film 724 is becoming smaller, so that it is approaching the crystalline grain 727 size in the polycrystalline substrate 722.

FIG. 7D shows an amorphous mask film 734 overlying a polycrystalline substrate 732, and adhered at points 733 to substrate 732. The mask film 734 has bucked due to a combination of conditions which occur when the aspect ratio of the mask film 734 and the lack of adhesion at points 735 attributed to the line width “w” of mask film 734 being less than the crystalline grain 737 size in the polycrystalline substrate 732.

### DETAILED DESCRIPTION OF EXEMPLARY EMBODIMENTS

As a preface to the detailed description, it should be noted that, as used in this specification and the appended claims, the singular forms “a”, “an”, and “the” include plural referents, unless the context clearly dictates otherwise.

I. An Apparatus Used to Etch Amorphous Mask Features

The embodiment examples of etched amorphous mask features and etched patterns in polysilicon substrates were produced in a CENTURA® Integrated Processing System available from Applied Materials, Inc., of Santa Clara, Calif. This apparatus is described in detail below; however, it is contemplated that other plasma etching apparatus known in the industry may be used to carry out the invention.

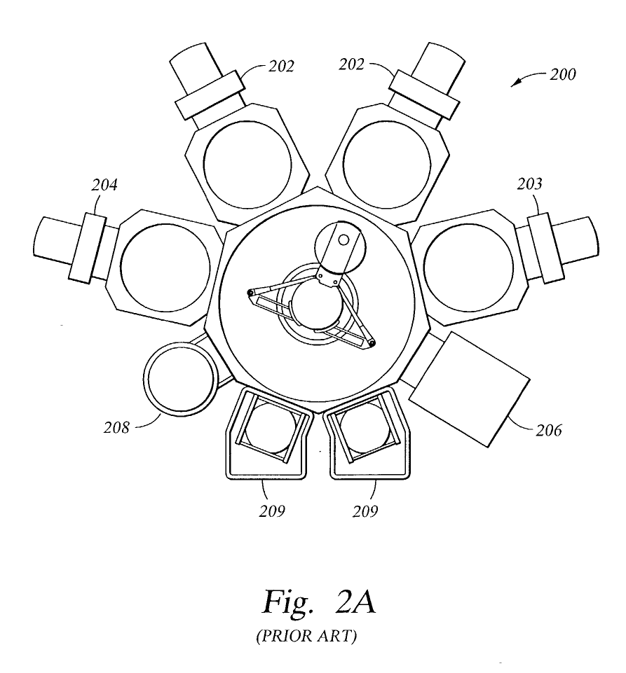

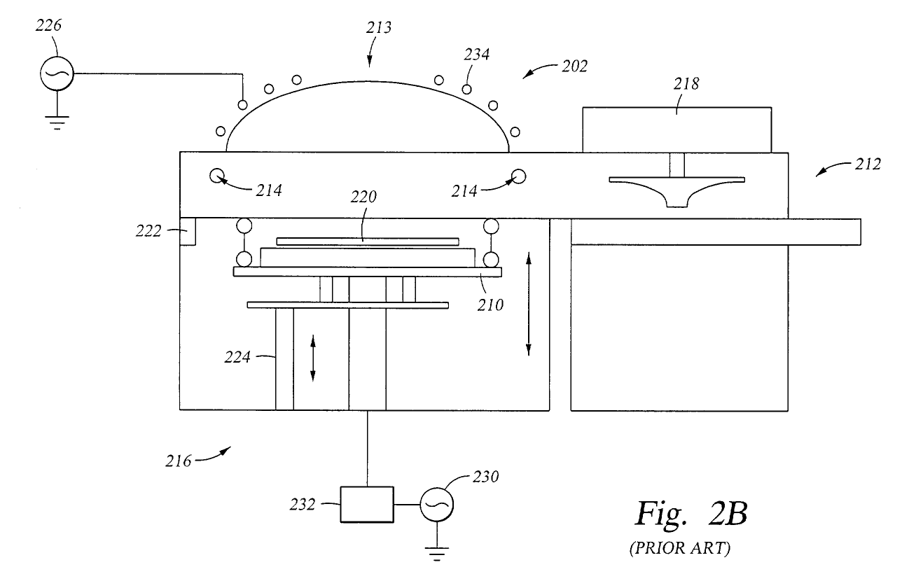

FIG. 2A shows an elevation schematic of the CENTURA® Integrated Processing System 200. The CENTURA® Integrated Processing System 200 is a fully automated semiconductor fabrication system, employing a single-wafer, multi-chamber, modular design which accommodates a variety of wafer sizes. For example, as shown in FIG. 2A, the CENTURA® etch system may include decoupled plasma source (DPS) etch chambers 202; CVD deposition chamber 203; advanced strip-arid-passivation (ASP) chamber 204; wafer orienter chamber 206; cooldown chamber 208; and independently operated loadlock chambers 209.

FIG. 2B is a schematic of an individual CENTURA® DPS™ etch chamber 202 of the type which may be used in the CENTURA) Integrated Processing System, commercially available from Applied Materials, Inc., Santa Clara, Calif. The equipment shown in schematic in FIG. 2B includes a Decoupled Plasma Source (DPS) of the kind described by Yan Ye et al. at the Proceedings of the Eleventh International Symposium of Plasma Processing, May 7, 1996, and as published in the Electrochemical Society Proceedings, Volume 96-12, pp. 222-233 (1996). The CENTURA® DPS™ etch chamber 202 is configured to be mounted on a standard CENTURA® mainframe.

The CENTURA® DPS™ etch chamber 202 consists of an upper chamber 212 having a ceramic dome 213, and a lower chamber 216. The lower chamber 216 includes an electrostatic chuck (ESC) cathode 210. Gas is introduced into the chamber via gas injection nozzles 214 for uniform gas distribution. Chamber pressure is controlled by a closed-loop pressure control system (not shown) with a throttle valve 218. During processing, a substrate 220 is introduced into the lower chamber 216 through inlet 222. The substrate 220 is held in place by means of a static charge generated on the surface of electrostatic chuck (ESC) cathode 210 by applying a DC voltage to a conductive layer located under a dielectric film on the chuck surface (not shown). The cathode 210 and substrate 220 are then raised by means of a wafer lift 224 and a seal is created against the upper chamber 212 in position for processing. Etch gases are introduced into the upper chamber 212 via the ceramic gas injection nozzles 214. The etch chamber 202 uses an inductively coupled plasma source power 226 operating at 2 MHZ, which is connected to inductive coil 234 for generating and sustaining a high density plasma. The wafer is biased with an RF source 230 and matching network 232 operating within the range of 200 kHz to 13.56 MHZ; more typically, within the range of 100 kHz to 2 MHZ. Power to the plasma source 226 and substrate biasing means 230 are controlled by separate controllers (not shown).

The temperature on the surface of the etch chamber walls is controlled using liquid-containing conduits (not shown) which are located in the walls of the etch chamber 202. The temperature of the semiconductor substrate is controlled using the temperature of the electrostatic chuck cathode 210 upon which the substrate 220 rests. Typically, a helium gas flow is used to facilitate heat transfer between the substrate and the pedestal.

As previously mentioned, although the etch process chamber used to process the substrates described in the Examples presented herein was an inductively coupled etch chamber of the kind shown in schematic in FIG. 2B, any of the etch processors available in the industry should be able to take advantage of the etch chemistry described herein, with some adjustment to other process parameters.

II. Exemplary Methods of the Invention:

### EXAMPLE ONE

### A General Etch Process for an Amorphous Carbon Mask

The general etch process for an amorphous carbon mask is described below with reference to a CVD amorphous carbon hard mask and with reference to an underlying polysilicon substrate. In particular, a typical device fabrication process which will employ the amorphous carbon mask is advanced patterning of poly-Si gate applications. However, the concepts and etch techniques described have much broader applicability, and may be extended to the fabrication of patterned amorphous carbon patterned masks used in combination with any substrate, as will be apparent to one skilled in the art.

A new amorphous carbon hard mask and an etch integration scheme has been developed to enable advanced patterning of poly-Si gate applications. The integration involves a dual layer mask stack consisting of a thin amorphous carbon layer with a thin SiON (silicon oxynitride) cap layer. The hard mask open through the SiON cap layer can be performed with a less than 100 nm thick photoresist, enabling the extension of conventional photo-resist trim processes. Additionally, a resistless amorphous carbon mask trim process can be performed to further shrink the gate CD. The key benefits of using a CVD amorphous carbon hardmask are: (1) the amorphous carbon plus SiON bi-layer serves as an antireflective device for both 248 nm and 193 nm photolithography; (2) the amorphous carbon masking material provides for highly selective etching of poly-Si, with selectivity for etching poly-Si relative to the amorphous carbon mask being as high as 6:1; (3) the amorphous carbon hard mask material remaining after etching strips easily in an oxygen plasma; and (4) the amorphous carbon mask can be trimmed to a precise dimension prior to etching of the poly-Si without the need for photoresist and the additional process steps the use of photoresist would require. We have achieved sub-30 nm poly-Si gate structures using 248 nm photolithography, and 40 nm poly-Si gate structures using 193 nm photolithography.

### EXAMPLE TWO

### Etching Of A Pattern Of Polysilicon Lines Using an AC Hard Mask

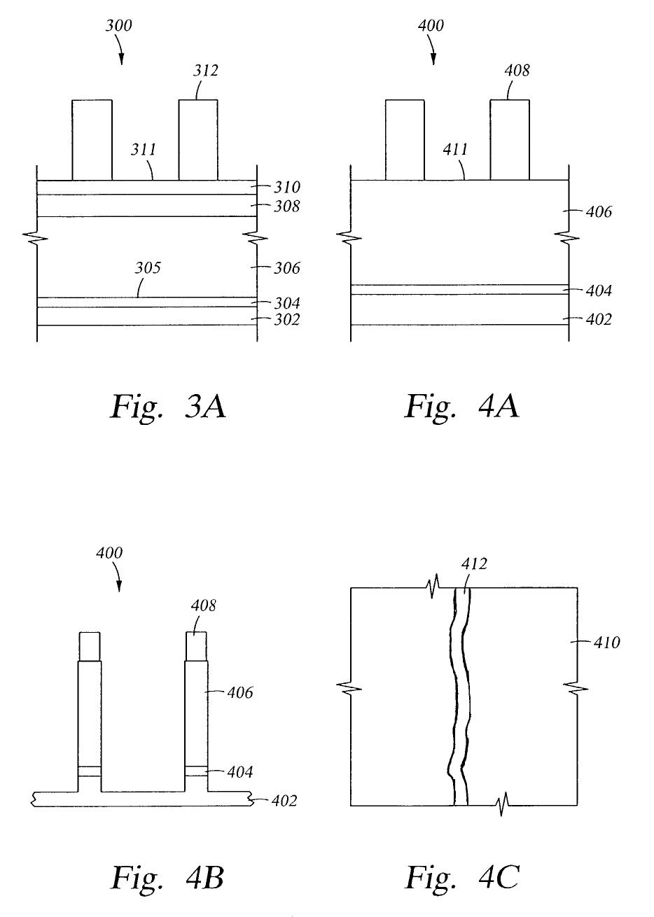

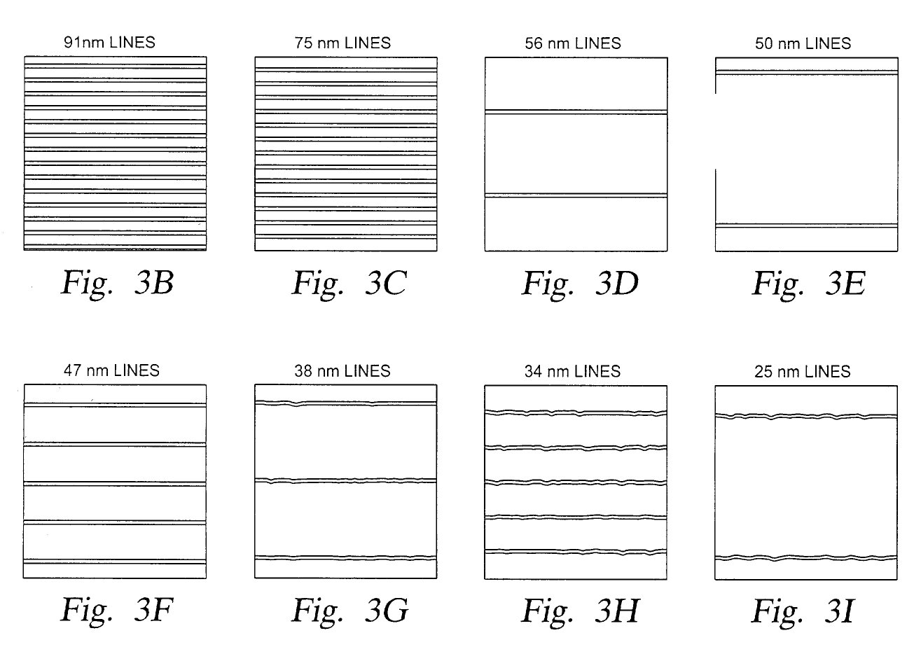

FIG. 3A shows a typical starting etch stack used to carry out a polysilicon etch process of the kind referenced above. The etch stack 300 included, from bottom to top, an underlying substrate of single crystal silicon 302; a thin (≈25 Å) layer of gate oxide 304; a 1,000 Å thick layer of polysilicon 306 overlying gate oxide 304; a 1,200 Å thick layer of amorphous carbon 308 overlying polysilicon layer 306; a layer 250 Å thick layer of silicon oxynitride 310 overlying amorphous carbon layer 308; and, a 3,000 Å thick layer of patterned 248 nm photoresist 312 on the upper surface 311 of silicon oxynitride layer 310.

The above-described structure provided a dual layer hard mask, including a capping layer of silicon oxynitride (SiON) and an amorphous carbon (AC) layer which was produced in the manner previously described herein with reference to application Ser. No. 09/590,322 filed Jun. 8, 2000 and entitled: “Method of Depositing Amorphous Carbon Layer”. The SiON capping film not only served as an ARC layer, but also enabled the photoresist trimming and rework (it is inert to both trimming and ashing etch chemistry, so can protect the underlying amorphous carbon layer). The thickness of the SiON layer is designed to offer the maximum reduction in light reflectivity, while permitting complete removal during a step in which the poly-Si is etched. For etching 1,500 Å-2,000 Å of poly-Si, a typical film stack will include 1,000 Å-5,000 Å of photoresist (248 nm or 193 nm); 150 Å-350 Å of SiON; 500 Å-800 Å of AC; the 1,500 Å-2,000 Åof poly-Si; 10 Å-30 Å of gate oxide; and an underlying single crystal silicon substrate.

The process sequence used to generate a gate pattern is as follows: (1) The patterned photoresist is typically trimmed in a manner known in the art to reduce the patterned line critical dimension (CD); (2) The pattern is transferred from the photoresist through the silicon oxynitride layer (the SiON is “opened”); (3) The pattern is transferred through the AC hardmask layer, with a simultaneous stripping of the remainder of the photoresist masking material; (4) Optionally, the AC hard mask may be trimmed to further reduce the CD of various features of the hard mask; (5) The poly-Si gate main etch and over etch is carried out, with residual SiON layer being consumed during this etching process; (6) Residual amorphous carbon hardmask is removed using an oxygen plasma. At least the first 5 steps may be carried out in a single processing chamber using a multi-step etch process recipe.

Etching of the SiON layer is typically carried out using a high density plasma having a density which ranges from about 5×10¹⁰ e⁻/cm³ to about 5×10¹² e⁻/cm³. Any chemistry known in the art for etching SiON may be used. Typically the etchant is a halogen, frequently including fluorine, and may be a fluorine-containing plasma species generated from a CF₄ plasma source gas, for example.

Etching of the AC hard mask layer is also carried out using a high density plasma. The etchant plasma should provide a high selectivity for the AC layer relative to the SiON layer. In general, this step may be carried out using etchant species generated from a plasma source gas that includes oxygen. Depending on the sidewall profile to be generated during etching of the AC hard mask layer, one or more plasma species that passivate sidewalls during the etch process may be used. Plasma source gases used to generate passivation species frequently include HCl, HBr, CH₃Br, CHCl₃, and combinations thereof, by way of example and not by way of limitation. In one example method, the AC mask layer is etched in the CENTURA® DPS™ process chamber described above, employing 9-27 sccm O₂, 20-60 sccm HBr, and 20-60 argon. Process pressure of 2-6 mTorr; plasma source power of 500-1500 W; substrate bias power of 75-225 W; substrate support pedestal temperature in the range of 50° C.; chamber wall temperature in the range of 65° C.; and a chamber dome temperature of about 80° C.

The poly-Si layer may be etched using any of the chemistries known in the art for etching silicon, with halogen-based systems being most commonly used. Often a two step process is carried out in which a more aggressive etch is carried out through the bulk of the polysilicon layer, with a less aggressive etch being carried out as a surface of the underlying oxide layer is approached. For example, using the CENTURA® DPS™ process chamber described above, the first etch step may employ 15-35 sccm CF₄, 50-150 sccm HBr, 30-90-sccm Cl₂, and 6-18 sccm HeO₂ (i.e., a mixture of 70% He and 30% O₂). Process pressure of 2-6 mTorr; plasma source power of 500-1300 W; substrate bias power of 40-120W; substrate support pedestal temperature in the range of 50° C.; chamber wall temperature in the range of 65° C.; and a chamber dome temperature of about 80° C. In the second step, the process conditions may be adjusted to: 50-150 sccm HBr, 5-15 sccm Cl₂, and 6-18 sccm HeO₂; process pressure of 15-35 mTorr; plasma source power of 400-1100 W; substrate bias power of 40-120 W; pedestal temperature in the range of 50° C.; chamber wall temperature in the range of 65° C.; and dome temperature in the range of 80° C.

With reference to FIG. 3A, after transferring the pattern from the photoresist layer 312 through the SiON layer 310, and then through the AC layer 308 and the poly-Si layer using the integrated process described above, the structure 300 was processed to consist essentially of the single crystal silicon substrate 302 with an overlying oxide layer 304, and with a pattern of poly-Si lines generated from poly-Si layer 306 adhered to the surface 305 of oxide layer 304.

FIGS. 3B-31 show a top view of a series etched film stacks, each of which was etched in the manner described above, to produce a pattern of poly-Si lines on an oxide substrate. Each etch stack was etched to provide a different poly-Si line width, i.e. a different line critical dimension (CD). All of the etched AC lines were approximately 120 nm in height. FIG. 3B shows the top view of etched lines which are 91 nm in line width. FIG. 3C shows the top view of etched lines which are 75 nm in line width. FIG. 3D shows the top view of etched lines which are 56 nm in line width. FIG. 3E shows etched lines which are 50 nm in line width. FIG. 3F shows etched lines which are 47 nm in line width; there are some minor indications of line distortion at a 47 nm line width. FIG. 3G shows etched lines which are 38 nm in line width, with definite occurrence of line buckling. FIG. 3H shows etched lines which are 34 nm in line width, with more severe and more frequent line buckling that observed for the 38 nm line width. FIG. 3I shows etched lines which are 25 nm in line width, with line buckling similar with that observed for the 34 nm line width poly-Si lines. The question then was what was causing the line buckling, whether the buckling was peculiar to etched poly-Si patterns, and what could be done about the problem.

### EXAMPLE THREE

### Test Etching of Silicon Nitride Lines to See Whether They Would Exhibit Sidewall Buckling

FIG. 4A shows a schematic cross-sectional view of starting etch stack used to carry out the patterned etching of lines and spaces through a layer of silicon nitride. The etch stack 400 included, from bottom to top, an underlying substrate of single crystal silicon 402; a thin, 150 Å thick, layer of gate oxide 304; a 1,800 Å thick layer of silicon nitride 406 overlying gate oxide 304; and a 3,000 Å thick layer of patterned 248 nm photoresist 408 on the upper surface 411 of silicon nitride layer 406.

The silicon nitride layer 406 may be etched using any of the chemistries known in the art for etching silicon silicon nitride, with fluorine-containing systems being most commonly used. For example, using a CENTURA® DPS II™ process chamber available from Applied Materials, Inc., the first etch step, to transfer the pattern from patterned photoresist layer 408 through silicon nitride layer 406 employed a plasma generated from a plasma source gas including 12 sccm of SF₆ and 400 sccm of CHF₃, with approximately 200 sccm of He dilution (heat transfer medium). Other process conditions included a process pressure of 25 mTorr; plasma source power of 300 W; substrate bias power of 400W; substrate support pedestal temperature in the range of 70° C.; and chamber wall and ceiling temperature in the range of 80° C. The etch time was 64 seconds.

The pattern was then transferred through silicon oxide layer 404 using a plasma generated from a plasma source gas including 60 sccm CHF3 and 180 sccm Ar, with approximately 200 sccm of He dilution. Other process conditions included a process pressure of 10 mTorr; plasma source power 400 W; substrate bias power 200 W; substrate support pedestal temperature in the range of 70° C.; and, chamber wall and ceiling temperature in the range of 80° C. The etch time was 30 seconds.

The pattern was then etched into the underlying single crystal substrate 402 surface a distance of about 60 nm, to provide a better indication of the buckling behavior of the etched silicon nitride line pattern. The continued etching guaranteed removal of all of the silicon nitride toward the bottom of silicon nitride layer 406. The etching into the silicon substrate included a “breakthrough” step in which the substrate was etched using a plasma generated from a plasma source gas of 120 sccm of CF4; 300 W of plasma source power; 40 W of substrate bias power; a process chamber pressure of 4 mTorr; a substrate support pedestal temperature in the range of 70° C.; and, chamber wall and ceiling temperature in the range of 80° C. The etch time was 10 seconds. The breakthrough step was followed by an etch into the silicon substrate 404 using a plasma generated from a plasma source gas including 35 seem of CF₄, 125 seem of HBr, 90 sccm of Cl₂, and 8 sccm of HeO₂ (i.e., a mixture of 70% He and 30% O₂). The process chamber pressure was 4 mTorr; the plasma source power was 600 W; and the substrate bias power was 80 W. The substrate support pedestal temperature was in the range of 70° C.; and, the chamber wall and ceiling temperature were in the range of 80° C. The etch time was 20 seconds.

With reference to FIG. 4A, the pattern was transferred from the photoresist layer 408 through the silicon nitride layer 406, the oxide layer 404 and into silicon substrate 402 approximately 60 nm. The line width for the silicon nitride line was 31 nm.

FIG. 4B shows a schematic side view of the structure 400 of FIG. 4A after completion of the etching process.

FIG. 4C shows a top view of a line 412 from FIG. 4B, with a small amount of photoresist 408 remaining at the top of line 412 and single crystal silicon substrate 402 exposed at the base of line 412. It is readily apparent from this top view that the line sidewall is buckled. This is an indication that line buckling occurs with silicon nitride etched lines as well as with polysilicon etched lines and is independent of whether the patterned mask used to etch the line is amorphous carbon or photoresist.

The line buckling problem, which seems to occur at line widths of about 50 nm or less, is apparently applicable to both amorphous and polycrystalline materials when etched to such line widths. The problem to be solved was how to etch pattern features having feature sizes of about 50 nm or less without experiencing line buckling of the masking material (which then translated into the underlying substrate being etched), and how to etch underlying substrates in general so that the patterned substrate features would not buckle.

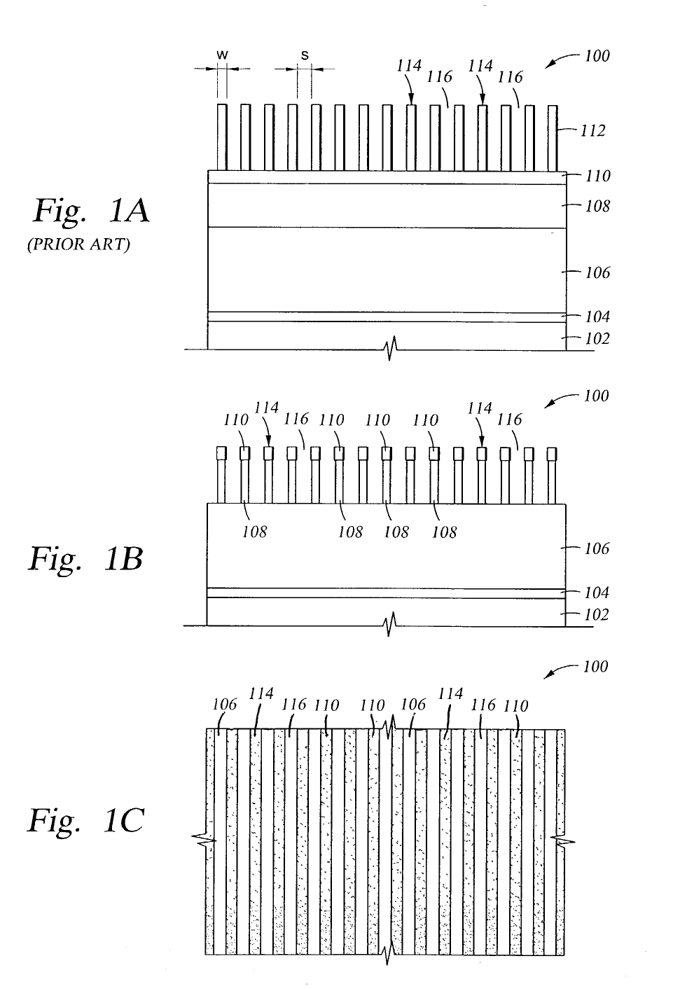

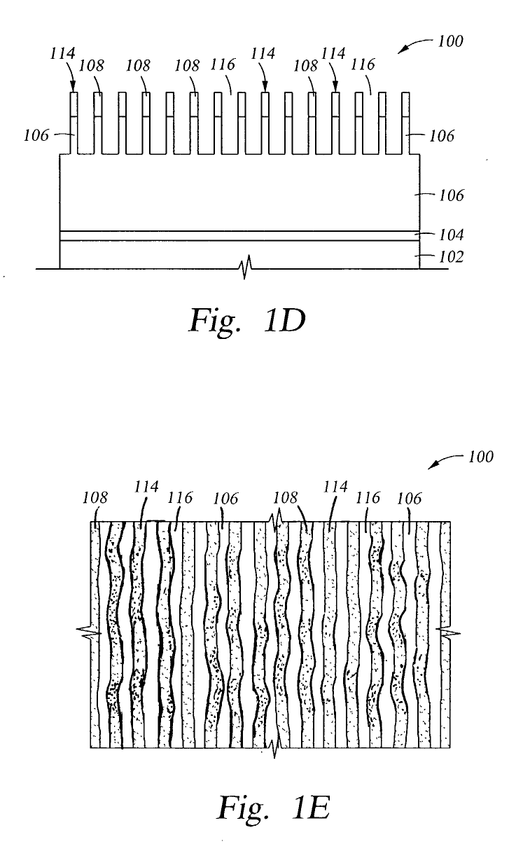

Our theory about the cause of line buckling, offered as a possible explanation and not by way of limitation of the present invention, is as follows. The layer being pattern etched is typically adhered to an underlying substrate, and in some instances may be adhered to an overlying etched layer as well. The tendency of a pattern etched feature to buckle along a line sidewall, for example, will depend on the degree of crystallinity in the layer being pattern etched. A more crystalline structure is less likely to buckle. In addition, when a pattern etched layer is adhered at the top to a capping layer of a material and at the bottom to a substrate to which there is good adhesion, this may help suppress the tendency of the sandwiched pattern etched layer to buckle. With reference to FIGS. 1B and 1C, the etched 38 nm wide AC hard mask lines, etched through the amorphous carbon (AC) layer 108 did not buckle when there was a SiON capping layer still present on the upper surface of etched AC layer 108. However, as illustrated in FIGS. 1D and 1E, once the SiON capping layer was gone (after etching about 35% of the distance into the polysilicon layer 106), the etched 38 nm wide and 120 nm high line buckled at the sidewalls.

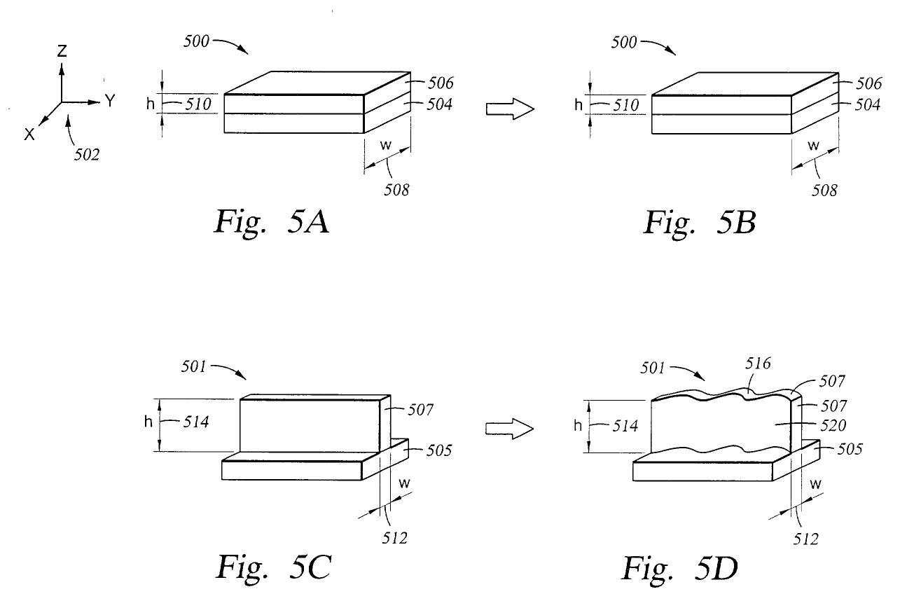

Amorphous and polycrystalline films always have some kind of internal stress, which is evidenced as localized stress at the interface between the film and the substrate underlying the film. With reference to the structure 500 shown in FIG. 5A, a polycrystalline or amorphous film 506 (having a line width “w” and a height “h”) is adhered to a crystalline substrate 504 (such as single crystal silicon). Since buckling of a sidewall of a patterned film occurs at the smallest dimensioned film surface, buckling in film 506 would occur in the z direction along height h 510. However, when the line width w 508 of the film 506 is much greater, or at least equal to, the height h 510 of the film, then buckling in the z direction is very unlikely, unless the film stress is exceptionally high. This is because, when the adhesion of film 506 to substrate 504 is good, and the bonding area between film 506 and substrate 504 is significantly large, the film 506 line is well supported by the substrate 504. No sidewall buckling of the film 506 occurs in either the z plane or the x-y plane, as illustrated in FIG. 5B. By comparison, with reference to FIG. 5C, when the height “h” 514 of the film line is much greater (more than about 3 times greater, for example) than the width “w” 512 of the film 507, the bonding (contact) area with the substrate 505 is much smaller, so that less support for the film 507 is provided by substrate 505. In addition, since the smallest dimension surface of film 507 is now the width w 512, buckling will occur along the sidewall 520 of film 507, in the x-y plane, as illustrated in FIG. 5D. It would be possible to further stabilize line 507 by using a capping layer (not shown) on the upper surface 516 of line 507.

### EXAMPLE FOUR

### Avoidance of Line Buckling in a Patterned Amorphous Film By Controlling the Aspect Ratio of Patterned Film Features.

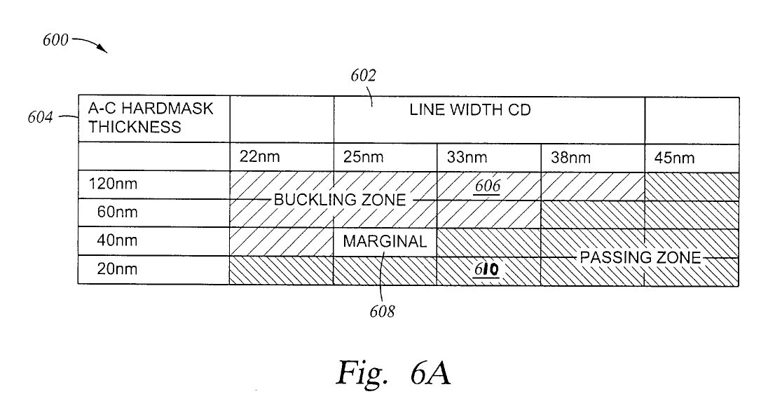

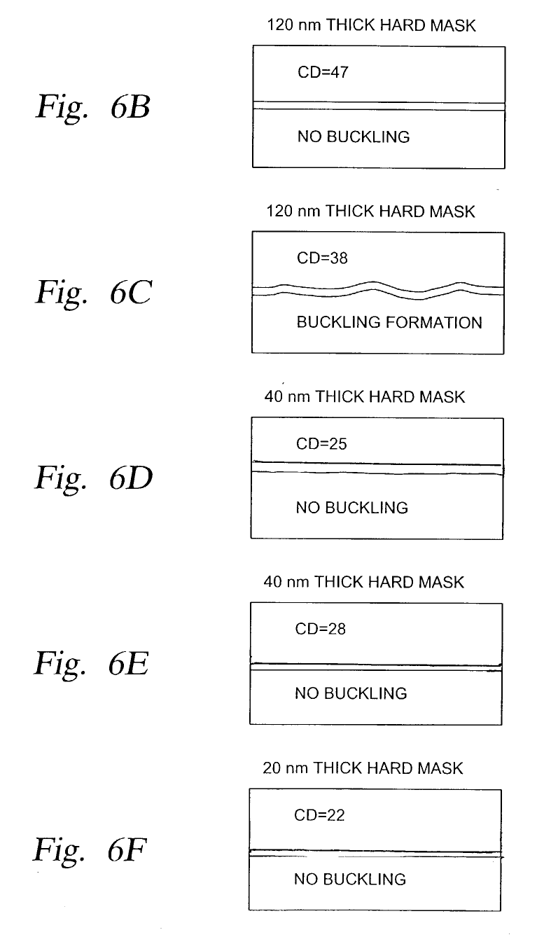

FIG. 6 is a bar graph 600 showing the tendency of an etch amorphous carbon mask feature to buckle, as a function of the aspect ratio of the mask feature, in particular the aspect ratio of an etched line. In this instance, the critical dimension (CD) line width for the mask feature is shown from left to right on the bar graph under heading 602, while the thickness 604 of the etched amorphous carbon hard mask (the height of a line feature) is shown on the left hand side of the bar graph. Area 606 of the bar graph is the “buckling zone” in which sidewalls of the mask feature were observed to buckle. Area 608 of the bar graph is the “marginal zone” in which sidewalls showed starting signs of or minor buckling. Area 610 of the bar graph is the “passing zone” in which sidewalls of the mask feature were observed not to buckle. This data is for an uncapped amorphous carbon hard mask adhered to a poly-Si substrate. This data indicates that as the line width CD for the mask feature decreases, the maximum aspect ratio which may be used for mask features must also decrease. For example, at a CD line width of 38 nm, to be in the passing zone, the aspect ratio of the feature should be controlled to be about 1.6 or less. At a CD of 33 nm, to be in the passing zone, the aspect ratio of the feature should be controlled to be about 1.2 or less. At a CD of 25 nm, to be in the passing zone, the aspect ratio of the feature should be controlled to be in the range of about 1.1 or 1.0; and at a CD of 22 nm, to be in the passing zone, the aspect ratio should be controlled to be about 0.9 or less.

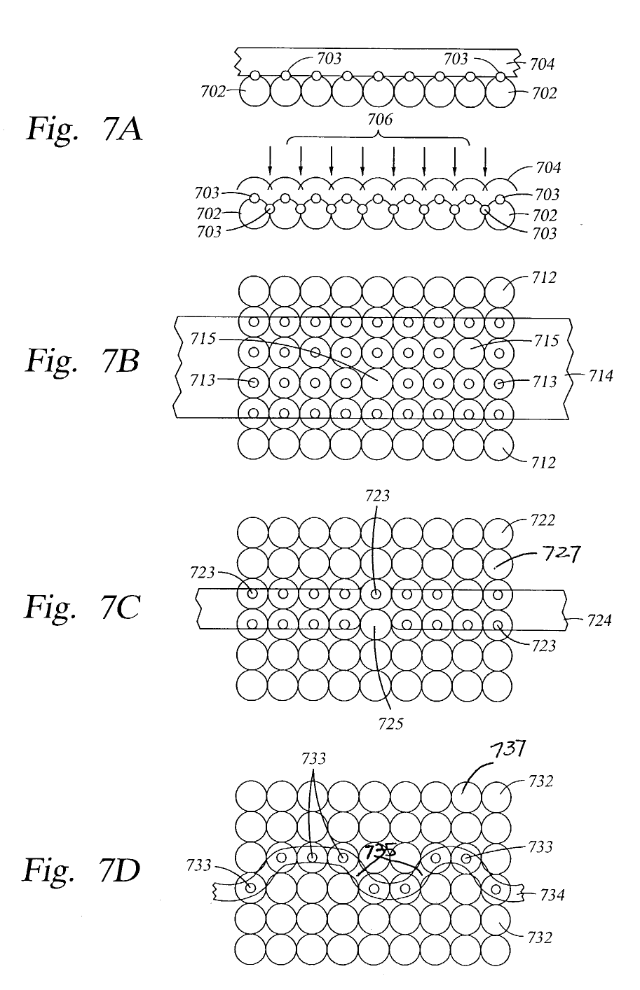

One theory which is offered as a possible explanation, and not by way of limitation, is that for a given line sidewall height, the tendency of the sidewall to buckle depends on the adhesion at the surface interfaces betw3een the etched feature and the substrate. FIG. 7A shows a schematic side view of an amorphous mask film 704 overlying a polycrystalline substrate 702, with microscopic point stress 706 illustrated within the mask film 704.

FIG. 7B shows a schematic of a tip view of FIG. 7A; a patterned line of an amorphous mask film 714 overlying a polycrystalline substrate 712, and adhered at points 713 to substrate 712. Because the line width “w” 717 of film 714 is considerably larger than the average diameter of a polycrystalline substrate 712 grain 711, there is good adhesion to polycrystalline substrate 712 and the tendency for amorphous mask film 714 to buckle is reduced.

FIG. 7C shows a schematic top view of a patterned line of an amorphous mask film 724 overlying a polycrystalline substrate 722, and adhered at points 723 to substrate 722, but not adhered at points 725. There is a higher tendency of the mask film 724 to buckle, due to the fact that the line width “w” 729 of mask film 724 is decreasing, so that it approaches the crystalline grain 727 size in the polycrystalline substrate 722.

FIG. 7D shows a schematic top view of a patterned line of an amorphous mask film 734 overlying a polycrystalline substrate 732, and adhered at points 733 to substrate 732. The mask line sidewall of film 734 has a very high tendency to buckle due to the lack of adhesion at points 735. This is attributed to the line width “w” 739 of mask film 734 being less than the crystalline grain 737 size in the polycrystalline substrate 732.

In view of the above examples, it is readily apparent that one skilled in the art can suppress or prevent feature sidewall buckling of either an amorphous or polycrystalline patterned mask feature, or feature etched using such a patterned mask, by controlling the aspect ratio of the mask feature in view of: (1) the mask feature CD; (2) the substrate to which the amorphous or polycrystalline feature is adhered; and, (3) any overlying, capping layer to which the amorphous or polycrystalline feature is adhered.

The above described exemplary embodiments are not intended to limit the scope of the present invention, as one skilled in the art can, in view of the present disclosure expand such embodiments to correspond with the subject matter of the invention claimed below.

We claim:

1. A method of preventing or suppressing the buckling of a patterned amorphous hard mask structure sidewall, wherein an aspect ratio of said patterned amorphous hard mask sidewall height to said sidewall width is controlled to be less than about 2 when said patterned hard mask sidewall width is less than about 50 nm in size.

2. A method in accordance with claim 1, wherein a substrate underlying said amorphous hard mask is a single crystal material or an amorphous material.

3. A method in accordance with claim 2, wherein said substrate is a single crystal material.

4. A method in accordance with claim 3, wherein said substrate is single crystal silicon.

5. A method in accordance with claim 1, wherein said substrate underlying said amorphous hard mask is a polycrystalline material and said aspect ratio of said patterned amorphous hard mask sidewall height to said sidewall width is controlled to be less than about 1.6.

6. A method in accordance with claim 5, wherein said sidewall width is about the same in dimension as said polycrystalline substrate grain size and said aspect ratio is controlled to be less than about 1.0.

7. A method in accordance with claim 6, wherein said polycrystalline substrate is polycrystalline silicon.

8. A method of preventing or suppressing the buckling of a patterned amorphous carbon hard mask structure sidewall, wherein an aspect ratio of said patterned amorphous hard mask sidewall height to said sidewall width is controlled to be less than about 2 when said patterned hard mask sidewall width is less than about 50 nm in size.

9. A method in accordance with claim 8, wherein a substrate underlying said amorphous carbon hard mask is a single crystal material or an amorphous material.

10. A method in accordance with claim 9 wherein said substrate is a single crystal material.

11. A method in accordance with claim 10, wherein said substrate is single crystal silicon.

12. A method in accordance with claim 11, wherein said substrate underlying said amorphous carbon hard mask is a polycrystalline material and said aspect ratio of said patterned amorphous carbon hard mask sidewall height to said sidewall width is controlled to be less than about 1.6.

13. A method in accordance with claim 12, wherein said sidewall width is about the same in dimension as said polycrystalline substrate grain size and said aspect ratio is controlled to be less than about 1.0.

14. A method in accordance with claim 13, wherein said polycrystalline substrate is polycrystalline silicon.

15. A method of preventing or suppressing buckling of a sidewall of a patterned amorphous masking material, wherein an aspect ratio of said sidewall height to said sidewall width is controlled based on said sidewall width when said sidewall width is about 50 nm or less.

16. A method in accordance with claim 15, wherein said line width is about 45 nm or less and said aspect ratio is controlled to be about 2.7 or less.

17. A method in accordance with claim 16, wherein said line width is about 38 nm or less and said aspect ratio is controlled to be about 1.6 or less.

18. A method in accordance with claim 17, wherein said line width is about 33 nm or less and said aspect ratio is controlled to be about 1.2 or less.

19. A method in accordance with claim 18, wherein said line width is about 25 nm or less and said aspect ratio is controlled to be about 1.1 or less.

20. A method in accordance with claim 19, wherein said line width is about 22 nm or less and said aspect ratio is controlled to be about 0.9 or less.

21. A method of preventing or suppressing buckling of a feature sidewall of a patterned amorphous masking material, wherein an aspect ratio of said feature sidewall height to said feature width is controlled based on said feature width, when said feature width is about 50 nm or less.

22. A method in accordance with claim 21, wherein said amorphous masking material is selected from the group consisting of amorphous carbon, silicon nitride, silicon oxide and combinations thereof.

23. A method in accordance with claim 22, wherein said patterned feature is a line having a line width is about 45 run or less and said aspect ratio is controlled to be about 2.7 or less.

24. A method in accordance with claim 23, wherein said patterned feature is a line having a line width is about 38 nm or less and said aspect ratio is controlled to be about 1.6 or less.

25. A method in accordance with claim 24, wherein said patterned feature is a line having a line width is about 33 nm or less and said aspect ratio is controlled to be about 1.2 or less.

26. A method in accordance with claim 25, wherein said patterned feature is a line having a line width is about 25 nm or less and said aspect ratio is controlled to be about 1.1 or less.

27. A method in accordance with claim 26, wherein said patterned feature is a line having a line width is about 22 nm or less and said aspect ratio is controlled to be about 0.9 or less.

28. A method in accordance with claim 21, wherein said amorphous masking material is deposited by a CVD technique.

29. A method in accordance with claim 22, wherein said amorphous carbon, silicon nitride, or silicon oxide is deposited using a CVD technique.

30. A method in accordance with claim 21, wherein said sidewall base is adhered to a single crystalline or amorphous substrate surface and said sidewall upper edge is restrained by a capping layer which includes at least some crystalline structure composition.

31. A method in accordance with claim 30, wherein said capping layer comprises silicon oxynitride.

32. A method in accordance with claim 21, wherein said sidewall base is adhered to a polycrystalline substrate and said sidewall upper edge is restrained by a capping layer which includes at least some crystalline structure composition.

33. A method in accordance with claim 32, wherein said capping layer comprises silicon oxynitride.

34. A method of preventing or suppressing buckling of a feature sidewall of a patterned amorphous material, wherein an aspect ratio of said feature sidewall height to said feature width is controlled based on said feature width, when said feature width is about 50 nm or less.

35. A method in accordance with claim 34, wherein said amorphous material is selected from the group consisting of amorphous carbon, silicon nitride, silicon oxide and combinations thereof.

36. A method in accordance with claim 35, wherein said patterned feature is a line having a line width is about 45 nm or less and said aspect ratio is controlled to be about 2.7 or less.

37. A method in accordance with claim 35, wherein said patterned feature is a line having a line width is about 38 nm or less and said aspect ratio is controlled to be about 1.6 or less.

38. A method in accordance with claim 35, wherein said patterned feature is a line having a line width is about 33 nm or less and said aspect ratio is controlled to be about 1.2 or less.

39. A method in accordance with claim 35, wherein said patterned feature is a line having a line width is about 25 nm or less and said aspect ratio is controlled to be about 1.1 or less.

40. A method in accordance with claim 26, wherein said patterned feature is a line having a line width is about 22 nm or less and said aspect ratio is controlled to be about 0.9 or less.
